(19) United States
(12) Patent Application Publication
(10) Pub. No.: US 2025/0240041 A1
(43) Pub. Date: Jul. 24, 2025

(54) TRANSMITTER ARCHITECTURE SUPPRESSING HARMONIC SIGNALS BETWEEN TRANSMITTERS USING A FILTER AND A RECONFIGURABLE POWER AMPLIFIER

(71) Applicant: QUALCOMM Incorporated, San Diego, CA (US)

(72) Inventors: Doohwan JUNG, Fremont, CA (US); Sang Oh LEE, Cupertino, CA (US); Hongbing WU, Saratoga, CA (US); Ayse YESILYURT, San Jose, CA (US)

(21) Appl. No.: 18/420,391

(22) Filed: Jan. 23, 2024

(51) Int. Cl. H04B 1/04; H03F 3/24

(52) U.S. Cl. CPC H04B 1/0475; H03F 3/245; H03F 2200/171; H03F 2200/294; H03F 2200/451; H04B 2001/0408

(57) ABSTRACT

Certain aspects of the present disclosure are directed towards apparatus and techniques for wireless communication. An example apparatus generally includes: a first transmitter circuit; a second transmitter circuit; a first transistor coupled between a supply node of the first transmitter circuit and a voltage rail; and a second transistor coupled between a supply node of the second transmitter circuit and the voltage rail.

### TECHNICAL FIELD

Certain aspects of the present disclosure generally relate to electronic circuits and, more particularly, to techniques and apparatus for signal transmission.

### BACKGROUND

Wireless communication devices are widely deployed to provide various communication services such as telephony, video, data, messaging, broadcasts, and so on. Such wireless communication devices may transmit and/or receive radio frequency (RF) signals via any of various suitable radio access technologies (RATs) including, but not limited to, 5G New Radio (NR), Long Term Evolution (LTE), Code Division Multiple Access (CDMA), Time Division Multiple Access (TDMA), Wideband CDMA (WCDMA), Global System for Mobility (GSM), Bluetooth, Bluetooth Low Energy (BLE), ZigBee, wireless local area network (WLAN) RATs (e.g., WiFi), and the like.

A wireless communication network may include a number of base stations or access points that can support communication for a number of mobile stations. A mobile station (MS) or access terminal may communicate with a base station (BS) or access point via a downlink and an uplink. The downlink (or forward link) refers to the communication link from the base station or access point to the mobile station or access terminal, and the uplink (or reverse link) refers to the communication link from the mobile station or access terminal to the base station or access point. A base station or access point may transmit data and control information on the downlink to the mobile station or access terminal. The base station or access point may also receive data and control information on the uplink from the mobile station or access terminal. The base station or access point and/or mobile station or access terminal may include multiple transmitters for signal transmissions.

### SUMMARY

The systems, methods, and devices of the disclosure each have several aspects, no single one of which is solely responsible for its desirable attributes. Without limiting the scope of this disclosure as expressed by the claims which follow, some features will now be discussed briefly. After considering this discussion, and particularly after reading the section entitled “Detailed Description,” one will understand how the features of this disclosure provide advantages that include reduced transmitter area consumption.

Certain aspects of the present disclosure are directed towards an apparatus for wireless communication. The apparatus generally includes: a first transmitter circuit; a second transmitter circuit; a first transistor coupled between a supply node of the first transmitter circuit and a voltage rail; and a second transistor coupled between a supply node of the second transmitter circuit and the voltage rail.

Certain aspects of the present disclosure are directed towards a method for wireless communication. The method generally includes: turning on a first transistor coupled between a supply node of a first transmitter circuit and a voltage rail; turning off a second transistor coupled between a supply node of a second transmitter circuit and the voltage rail; and generating, via the first transmitter circuit, a signal for transmission when the first transistor is turned on and the second transistor is turned off.

Certain aspects of the present disclosure are directed towards a wireless device. The wireless device generally includes: at least one antenna; a first transmitter circuit coupled to the at least one antenna; a second transmitter circuit coupled to the at least one antenna; a first transistor coupled between a supply node of the first transmitter circuit and a voltage rail; and a second transistor coupled between a supply node of the second transmitter circuit and the voltage rail.

Certain aspects of the present disclosure are directed towards an apparatus for wireless communication. The apparatus generally includes: a first transmitter circuit including a first amplifier; a second transmitter circuit including a second amplifier; a first transistor coupled between a supply node of the first transmitter circuit and a voltage rail; a second transistor coupled between a supply node of the second transmitter circuit and the voltage rail; and a filter coupled to a gate of the second transistor.

Certain aspects of the present disclosure are directed towards a wireless device. The wireless device generally includes: a first antenna; a second antenna; a 2 GHz WiFi transmitter circuit coupled to the first antenna; a 5 GHz WiFi transmitter circuit coupled to the second antenna; a first transistor coupled between a supply node of the first transmitter circuit and a voltage rail; and a second transistor coupled between a supply node of the second transmitter circuit and the voltage rail.

To the accomplishment of the foregoing and related ends, the one or more aspects comprise the features hereinafter fully described and particularly pointed out in the claims. The following description and the annexed drawings set forth in detail certain illustrative features of the one or more aspects. These features are indicative, however, of but a few of the various ways in which the principles of various aspects may be employed, and this description is intended to include all such aspects and their equivalents.

### BRIEF DESCRIPTION OF THE DRAWINGS

So that the manner in which the above-recited features of the present disclosure can be understood in detail, a more particular description, briefly summarized above, may be had by reference to aspects, some of which are illustrated in the appended drawings. It is to be noted, however, that the appended drawings illustrate only certain typical aspects of this disclosure and are therefore not to be considered limiting of its scope, for the description may admit to other equally effective aspects.

FIG. 1 is a diagram of an example wireless communications network, in which aspects of the present disclosure may be practiced.

FIG. 2 is a block diagram conceptually illustrating a design of an example base station (BS) or access point (AP) and user equipment (UE), in which aspects of the present disclosure may be practiced.

FIG. 3 is a block diagram of an example radio frequency (RF) transceiver, in which aspects of the present disclosure may be practiced.

FIG. 4 illustrates a shared supply path for multiple transmitters.

FIG. 5 illustrates transmitter circuitry including multiple transmitters having a shared supply path and respective head switches, in accordance with certain aspects of the present disclosure.

FIGS. 6 and 7 illustrate transmitter circuitry including multiple transmitters having a shared supply path and respective head switches with a low-impedance path through an amplifier, in accordance with certain aspects of the present disclosure.

FIG. 8 is a flow diagram illustrating example operations for wireless communication, in accordance with certain aspects of the present disclosure.

To facilitate understanding, identical reference numerals have been used, where possible, to designate identical elements that are common to the figures. It is contemplated that elements disclosed in one aspect may be beneficially utilized on other aspects without specific recitation.

### DETAILED DESCRIPTION

Certain aspects of the present disclosure are directed towards circuitry and techniques for suppressing electrical coupling of signal components between transmitters that share a common voltage rail. For example, a first head switch (HSW) may be coupled between the common voltage rail and a first transmitter, and a second HSW may be coupled between the common voltage rail and a second transmitter, reducing the electrical coupling from the first transmitter to the second transmitter while the first transmitter is active when the second HSW is open. In some aspects, a filter may be coupled to a gate of a transistor used to implement the second HSW to attenuate the harmonic signal from the first transmitter. In some cases, one or more switches of an amplifier of the second transmitter may be used to direct the harmonic signal to a reference potential node (e.g., electrical ground), as described in more detail herein.

Various aspects of the disclosure are described more fully hereinafter with reference to the accompanying drawings. This disclosure may, however, be embodied in many different forms and should not be construed as limited to any specific structure or function presented throughout this disclosure. Rather, these aspects are provided so that this disclosure will be thorough and complete, and will fully convey the scope of the disclosure to those skilled in the art. Based on the teachings herein one skilled in the art should appreciate that the scope of the disclosure is intended to cover any aspect of the disclosure disclosed herein, whether implemented independently of or combined with any other aspect of the disclosure. For example, an apparatus may be implemented or a method may be practiced using any number of the aspects set forth herein. In addition, the scope of the disclosure is intended to cover such an apparatus or method which is practiced using other structure, functionality, or structure and functionality in addition to or other than the various aspects of the disclosure set forth herein. It should be understood that any aspect of the disclosure disclosed herein may be embodied by one or more elements of a claim.

The word “exemplary” is used herein to mean “serving as an example, instance, or illustration.” Any aspect described herein as “exemplary” is not necessarily to be construed as preferred or advantageous over other aspects.

As used herein, the term “connected with” in the various tenses of the verb “connect” may mean that element A is directly connected to element B or that other elements may be connected between elements A and B (i.e., that element A is indirectly connected with element B). In the case of electrical components, the term “connected with” may also be used herein to mean that a wire, trace, or other electrically conductive material is used to electrically connect elements A and B (and any components electrically connected therebetween).

### An Example Wireless System

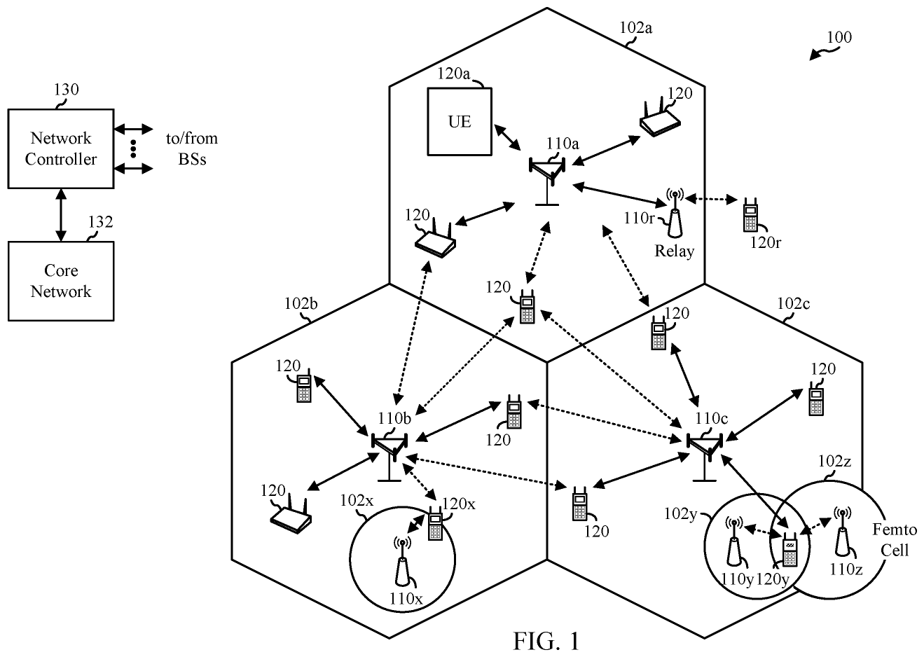

FIG. 1 illustrates an example wireless communications network 100, in which aspects of the present disclosure may be practiced. For example, the wireless communications network 100 may be a New Radio (NR) system (e.g., a Fifth Generation (5G) NR network), an Evolved Universal Terrestrial Radio Access (E-UTRA) system (e.g., a Fourth Generation (4G) network), a Universal Mobile Telecommunications System (UMTS) (e.g., a Second Generation/Third Generation (2G/3G) network), or a code division multiple access (CDMA) system (e.g., a 2G/3G network), or may be configured for communications according to an IEEE standard such as one or more of the 802.11 standards, etc.

As illustrated in FIG. 1, the wireless communications network 100 may include a number of base stations (BSs) 110a-z (each also individually referred to herein as “BS 110” or collectively as “BSs 110”) and other network entities. A BS may also be referred to as an access point (AP), an evolved Node B (eNodeB or eNB), a next generation Node B (gNodeB or gNB), or some other terminology.

A BS 110 may provide communication coverage for a particular geographic area, sometimes referred to as a “cell,” which may be stationary or may move according to the location of a mobile BS. In some examples, the BSs 110 may be interconnected to one another and/or to one or more other BSs or network nodes (not shown) in wireless communications network 100 through various types of backhaul interfaces (e.g., a direct physical connection, a wireless connection, a virtual network, or the like) using any suitable transport network. In the example shown in FIG. 1, the BSs 110a, 110b, and 110c may be macro BSs for the macro cells 102a, 102b, and 102c, respectively. The BS 110x may be a pico BS for a pico cell 102x. The BSs 110y and 110z may be femto BSs for the femto cells 102y and 102z, respectively. A BS may support one or multiple cells.

The BSs 110 communicate with one or more user equipments (UEs) 120a-y (each also individually referred to herein as “UE 120” or collectively as “Ues 120”) in the wireless communications network 100. A UE may be fixed or mobile and may also be referred to as a user terminal (UT), a mobile station (MS), an access terminal, a station (STA), a client, a wireless device, a mobile device, or some other terminology. A user terminal may be a wireless device, such as a cellular phone, a smartphone, a personal digital assistant (PDA), a handheld device, a wearable device, a wireless modem, a laptop computer, a tablet, a personal computer, etc.

The BSs 110 are considered transmitting entities for the downlink and receiving entities for the uplink. The UEs 120 are considered transmitting entities for the uplink and receiving entities for the downlink. As used herein, a “transmitting entity” is an independently operated apparatus or device capable of transmitting data via a frequency channel, and a “receiving entity” is an independently operated apparatus or device capable of receiving data via a frequency channel. In the following description, the subscript “dn” denotes the downlink, the subscript “up” denotes the uplink. Nᵤₚ Ues may be selected for simultaneous transmission on the uplink, N_{dn} Ues may be selected for simultaneous transmission on the downlink. Nᵤₚ may or may not be equal to N_{dn}, and Nᵤₚ and N_{dn} may be static values or can change for each scheduling interval. Beam-steering or some other spatial processing technique may be used at the BSs 110 and/or Ues 120.

The Ues 120 (e.g., 120x, 120y, etc.) may be dispersed throughout the wireless communications network 100, and each UE 120 may be stationary or mobile. The wireless communications network 100 may also include relay stations (e.g., relay station 110r), also referred to as relays or the like, that receive a transmission of data and/or other information from an upstream station (e.g., a BS 110a or a UE 120r) and send a transmission of the data and/or other information to a downstream station (e.g., a UE 120 or a BS 110), or that relays transmissions between Ues 120, to facilitate communication between devices.

The BSs 110 may communicate with one or more Ues 120 at any given moment on the downlink and uplink. The downlink (i.e., forward link) is the communication link from the BSs 110 to the Ues 120, and the uplink (i.e., reverse link) is the communication link from the Ues 120 to the BSs 110. A UE 120 may also communicate peer-to-peer with another UE 120.

The wireless communications network 100 may use multiple transmit and multiple receive antennas for data transmission on the downlink and uplink. BSs 110 may be equipped with a number Nₐₚ of antennas to achieve transmit diversity for downlink transmissions and/or receive diversity for uplink transmissions. A set Nᵤ of Ues 120 may receive downlink transmissions and transmit uplink transmissions. Each UE 120 may transmit user-specific data to and/or receive user-specific data from the BSs 110. In general, each UE 120 may be equipped with one or multiple antennas. The Nᵤ Ues 120 can have the same or different numbers of antennas.

The wireless communications network 100 may be a time division duplex (TDD) system or a frequency division duplex (FDD) system. For a TDD system, the downlink and uplink share the same frequency band. For an FDD system, the downlink and uplink use different frequency bands. The wireless communications network 100 may also utilize a single carrier or multiple carriers for transmission. Each UE 120 may be equipped with a single antenna (e.g., to keep costs down) or multiple antennas (e.g., where the additional cost can be supported).

A network controller 130 (also sometimes referred to as a “system controller”) may be in communication with a set of BSs 110 and provide coordination and control for these BSs 110 (e.g., via a backhaul). In certain cases (e.g., in a 5G NR system), the network controller 130 may include a centralized unit (CU) and/or a distributed unit (DU). In certain aspects, the network controller 130 may be in communication with a core network 132 (e.g., a 5G Core Network (5GC)), which provides various network functions such as Access and Mobility Management, Session Management, User Plane Function, Policy Control Function, Authentication Server Function, Unified Data Management, Application Function, Network Exposure Function, Network Repository Function, Network Slice Selection Function, etc.

In certain aspects of the present disclosure, the BSs 110 and/or the Ues 120 may include multiple transmitters sharing a common voltage rail using respective head switches, as described in more detail herein.

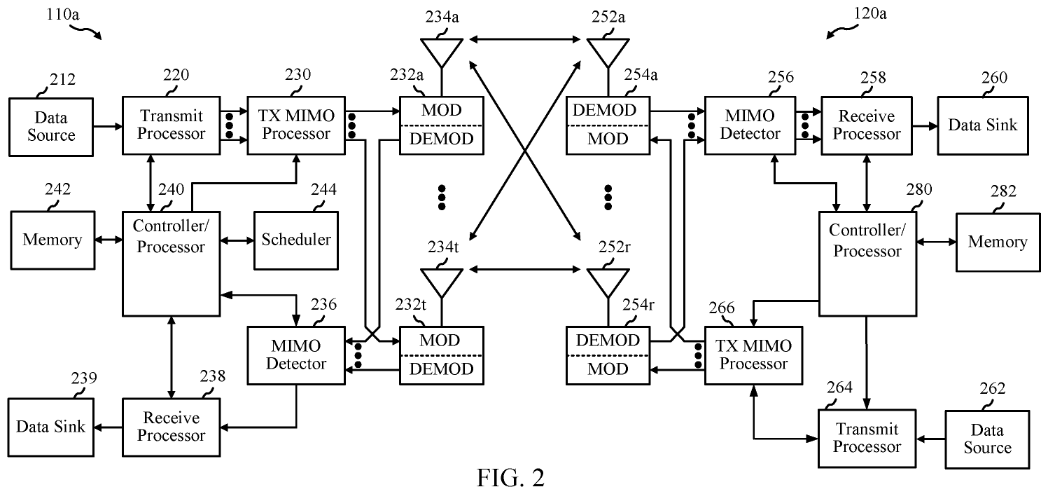

FIG. 2 illustrates example components of BS 110a and UE 120a (e.g., from the wireless communications network 100 of FIG. 1), in which aspects of the present disclosure may be implemented.

On the downlink, at the BS 110a, a transmit processor 220 may receive data from a data source 212, control information from a controller/processor 240, and/or possibly other data (e.g., from a scheduler 244). The various types of data may be sent on different transport channels. For example, the control information may be designated for the physical broadcast channel (PBCH), physical control format indicator channel (PCFICH), physical hybrid automatic repeat request (HARQ) indicator channel (PHICH), physical downlink control channel (PDCCH), group common PDCCH (GC PDCCH), etc. The data may be designated for the physical downlink shared channel (PDSCH), etc. A medium access control (MAC)-control element (MAC-CE) is a MAC layer communication structure that may be used for control command exchange between wireless nodes. The MAC-CE may be carried in a shared channel such as a PDSCH, a physical uplink shared channel (PUSCH), or a physical sidelink shared channel (PSSCH).

The processor 220 may process (e.g., encode and symbol map) the data and control information to obtain data symbols and control symbols, respectively. The transmit processor 220 may also generate reference symbols, such as for the primary synchronization signal (PSS), secondary synchronization signal (SSS), PBCH demodulation reference signal (DMRS), and channel state information reference signal (CSI-RS).

A transmit (TX) multiple-input, multiple-output (MIMO) processor 230 may perform spatial processing (e.g., precoding) on the data symbols, the control symbols, and/or the reference symbols, if applicable, and may provide output symbol streams to the modulators (MODs) in transceivers 232a-232t. Each modulator in transceivers 232a-232t may process a respective output symbol stream (e.g., for orthogonal frequency division multiplexing (OFDM), etc.) to obtain an output sample stream. Each of the transceivers 232a-232t may further process (e.g., convert to analog, amplify, filter, and upconvert) the output sample stream to obtain a downlink signal. Downlink signals from the transceivers 232a-232t may be transmitted via the antennas 234a-234t, respectively.

At the UE 120a, the antennas 252a-252r may receive the downlink signals from the BS 110a and may provide received signals to the transceivers 254a-254r, respectively. The transceivers 254a-254r may condition (e.g., filter, amplify, downconvert, and digitize) a respective received signal to obtain input samples. Each demodulator (DEMOD) in the transceivers 232a-232t may further process the input samples (e.g., for OFDM, etc.) to obtain received symbols. A MIMO detector 256 may obtain received symbols from the demodulators in transceivers 254a-254r, perform MIMO detection on the received symbols if applicable, and provide detected symbols. A receive processor 258 may process (e.g., demodulate, deinterleave, and decode) the detected symbols, provide decoded data for the UE 120a to a data sink 260, and provide decoded control information to a controller/processor 280.

On the uplink, at UE 120a, a transmit processor 264 may receive and process data (e.g., for the physical uplink shared channel (PUSCH)) from a data source 262 and control information (e.g., for the physical uplink control channel (PUCCH)) from the controller/processor 280. The transmit processor 264 may also generate reference symbols for a reference signal (e.g., the sounding reference signal (SRS)). The symbols from the transmit processor 264 may be precoded by a TX MIMO processor 266 if applicable, further processed by the modulators (MODs) in transceivers 254a-254r (e.g., for single-carrier frequency division multiplexing (SC-FDM), etc.), and transmitted to the BS 110a. At the BS 110a, the uplink signals from the UE 120a may be received by the antennas 234, processed by the demodulators in transceivers 232a-232t, detected by a MIMO detector 236 if applicable, and further processed by a receive processor 238 to obtain decoded data and control information sent by the UE 120a. The receive processor 238 may provide the decoded data to a data sink 239 and the decoded control information to the controller/processor 240.

The memories 242 and 282 may store data and program codes for BS 110a and UE 120a, respectively. The memories 242 and 282 may also interface with the controllers/processors 240 and 280, respectively. A scheduler 244 may schedule Ues for data transmission on the downlink and/or uplink.

In certain aspects of the present disclosure, the transceivers 232 and/or the transceivers 254 may include multiple transmitters sharing a common voltage rail using respective head switches, as described in more detail herein.

NR may utilize orthogonal frequency division multiplexing (OFDM) with a cyclic prefix (CP) on the uplink and downlink. NR may support half-duplex operation using time division duplexing (TDD). OFDM and single-carrier frequency division multiplexing (SC-FDM) partition the system bandwidth into multiple orthogonal subcarriers, which are also commonly referred to as tones, bins, etc. Each subcarrier may be modulated with data. Modulation symbols may be sent in the frequency domain with OFDM and in the time domain with SC-FDM. The spacing between adjacent subcarriers may be fixed, and the total number of subcarriers may be dependent on the system bandwidth. The system bandwidth may also be partitioned into subbands. For example, a subband may cover multiple resource blocks (RBs).

### Example RF Transceiver

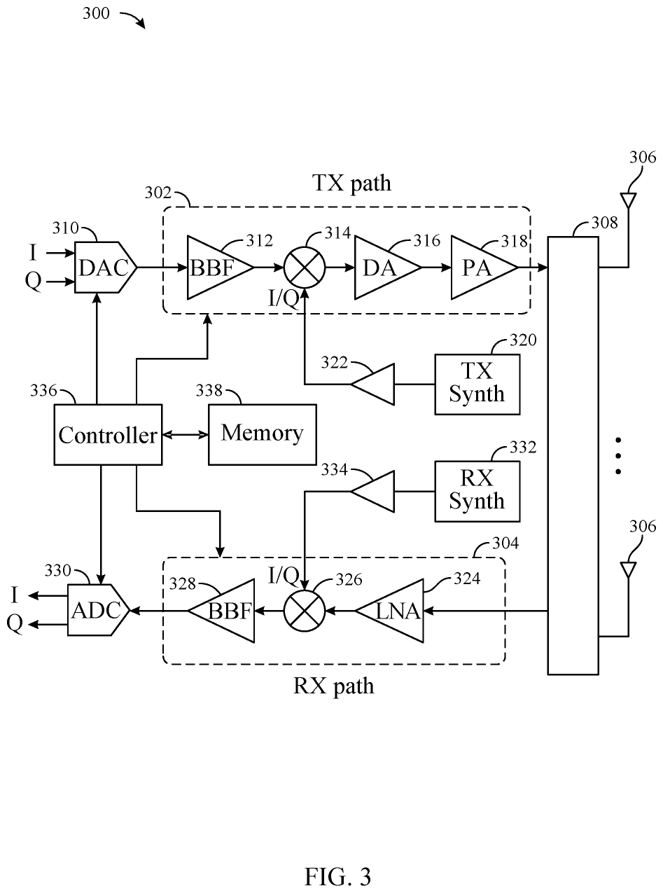

FIG. 3 is a block diagram of an example radio frequency (RF) transceiver circuit 300, in accordance with certain aspects of the present disclosure. The RF transceiver circuit 300 includes at least one transmit (TX) path 302 (also known as a “transmit chain”) for transmitting signals via one or more antennas 306 and at least one receive (RX) path 304 (also known as a “receive chain”) for receiving signals via the antennas 306. When the TX path 302 and the RX path 304 share an antenna 306, the paths may be connected with the antenna via an interface 308, which may include any of various suitable RF devices, such as a switch, a duplexer, a diplexer, a multiplexer, and the like.

Receiving in-phase (I) and/or quadrature (Q) baseband analog signals from a digital-to-analog converter (DAC) 310, the TX path 302 may include a baseband filter (BBF) 312, a mixer 314, a driver amplifier (DA) 316, and a power amplifier (PA) 318. The BBF 312, the mixer 314, the DA 316, and the PA 318 may be included in a radio frequency integrated circuit (RFIC). For certain aspects, the PA 318 may be external to the RFIC. In some aspects, a common voltage rail may be used for multiple Pas, such as the PA 318, as described in more detail herein.

The BBF 312 filters the baseband signals received from the DAC 310, and the mixer 314 mixes the filtered baseband signals with a transmit local oscillator (LO) signal to convert the baseband signal of interest to a different frequency (e.g., upconvert from baseband to a radio frequency). This frequency-conversion process produces the sum and difference frequencies between the LO frequency and the frequencies of the baseband signal of interest. The sum and difference frequencies are referred to as the “beat frequencies.” The beat frequencies are typically in the RF range, such that the signals output by the mixer 314 are typically RF signals, which may be amplified by the DA 316 and/or by the PA 318 before transmission by the antenna(s) 306. While one mixer 314 is illustrated, several mixers may be used to upconvert the filtered baseband signals to one or more intermediate frequencies and to thereafter upconvert the intermediate frequency (IF) signals to a frequency for transmission.

The RX path 304 may include a low noise amplifier (LNA) 324, a mixer 326, and a baseband filter (BBF) 328. The LNA 324, the mixer 326, and the BBF 328 may be included in one or more RFICs, which may or may not be the same RFIC that includes the TX path components. RF signals received via the antenna(s) 306 may be amplified by the LNA 324, and the mixer 326 mixes the amplified RF signals with a receive local oscillator (LO) signal to convert the RF signal of interest to a different baseband frequency (e.g., downconvert). The baseband signals output by the mixer 326 may be filtered by the BBF 328 before being converted by an analog-to-digital converter (ADC) 330 to digital I and/or Q signals for digital signal processing.

Certain transceivers may employ frequency synthesizers with a variable-frequency oscillator (e.g., a voltage-controlled oscillator (VCO) or a digitally controlled oscillator (DCO)) to generate a stable, tunable LO with a particular tuning range. Thus, the transmit LO may be produced by a TX frequency synthesizer 320, which may be buffered or amplified by amplifier 322 before being mixed with the baseband signals in the mixer 314. Similarly, the receive LO may be produced by an RX frequency synthesizer 332, which may be buffered or amplified by amplifier 334 before being mixed with the RF signals in the mixer 326. For certain aspects, a single frequency synthesizer may be used for both the TX path 302 and the RX path 304. In certain aspects, the TX frequency synthesizer 320 and/or RX frequency synthesizer 332 may include a frequency multiplier, such as a frequency doubler, that is driven by an oscillator (e.g., a VCO) in the frequency synthesizer.

A controller 336 (e.g., controller/processor 280 in FIG. 2) may direct the operation of the RF transceiver circuit 300A, such as transmitting signals via the TX path 302 and/or receiving signals via the RX path 304. The controller 336 may be a processor, a digital signal processor (DSP), an application-specific integrated circuit (ASIC), a field-programmable gate array (FPGA) or other programmable logic device (PLD), discrete gate or transistor logic, discrete hardware components, or any combination thereof. A memory 338 (e.g., memory 282 in FIG. 2) may store data and/or program codes for operating the RF transceiver circuit 300. The controller 336 and/or the memory 338 may include control logic (e.g., complementary metal-oxide-semiconductor (CMOS) logic).

While FIGS. 1-3 provide wireless communications as an example application in which certain aspects of the present disclosure may be implemented to facilitate understanding, certain aspects described herein may be used for any of various other suitable systems.

### Example Techniques for Suppressing Electrical Coupling of Harmonics between Transmitters

As advanced chip fabrication processes are used, chip sizes are becoming smaller, and the number of balls that can be used in a package is reduced. In addition, the number of balls in the chip may be reduced to reduce costs. To this end, the number of balls in radio frequency (RF) transmitters may be reduced by sharing power supply balls (e.g., a voltage rail) between transmitters (e.g., a transmitter configured for transmitting signals around 2.4 GHz and a transmitter configured for transmitting signals around 5 GHz (e.g., two WiFi transmitters). However, in this case, a harmonic signal (e.g., such as a second harmonic signal) generated from a first transmitter (e.g., generated by a power amplifier (PA) of a 2.4 GHz transmitter) may be conductively coupled to a second transmitter output through the shared supply path (e.g., shared voltage rail path). The harmonic signal may include a second harmonic which may have a frequency that is twice the local oscillator (LO) frequency (2flo) plus twice the baseband frequency (2fbb). The electrically coupled second harmonic signal from the first transmitter may be close in frequency to the signal band associated with the second band (e.g., around 5 GHZ). Thus, an off-chip filter with a sharp roll-off may be used to attenuate the harmonic signal from the first transmitter, which increases the off-chip filter overhead and cost. In some cases, the PA may be driven with more power to operate in a more linear region, reducing the second harmonic frequency signal. However, increasing the power consumption of the PA reduces the transmitter efficiency, which is especially disadvantageous in internet-of-things (IoT) applications where lower power consumption is important (e.g., especially given that the PA is the most power-hungry block in the transmitter). Without mitigation of the harmonic signal from the first transmitter, a Federal Communications Commission (FCC) (or other similar regulatory agency) violation (e.g., an emissions violation) may occur at the second harmonic frequency due to the signal electrically coupled to the second transmitter output during the first transmitter operation mode.

In some aspects, the first transmitter described herein may include a 2.4 GHZ WiFi transmitter (e.g., a transmitter operating around 2.4 GHZ) and the second transmitter described herein may be a 5 GHz WiFi transmitter (e.g., a transmitter operating around 5 GHz). While some examples provided herein have been described with respect to WiFi transmitters, it should be appreciated that certain aspects of the present disclosure may be applied to other systems with transmitters sharing a supply path.

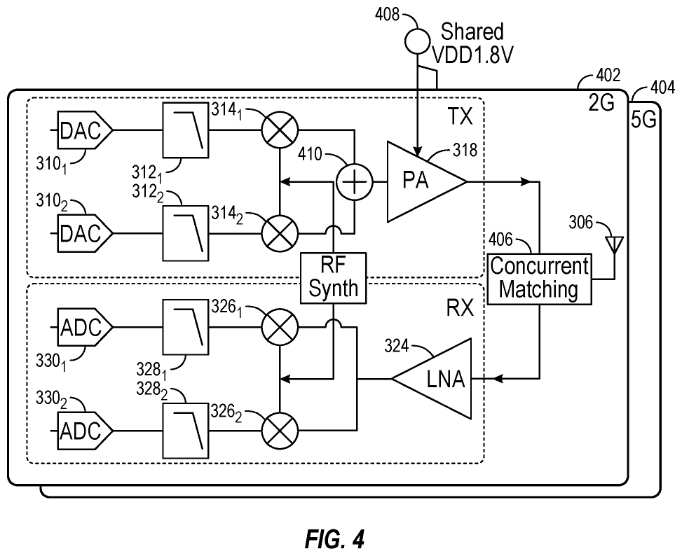

FIG. 4 illustrates a shared supply path for a first transceiver 402 (e.g., a 2G transceiver, also referred to as a 2.4 GHz transceiver) and a second transceiver 404 (e.g., a 5G transceiver, also referred to as a 5 GHz transceiver). As shown, the first transceiver 402 may include a DAC 3101 for an in-phase (I) signal and a DAC 3102 for a quadrature (Q) signal, corresponding to the DAC 310 of FIG. 3. The outputs of DACs 310₁ and 310₂ may be coupled to respective filters 312₁ and 312₂ (e.g., corresponding to BBF 312 of FIG. 3) and mixers 314₁ and 314₂ (e.g., corresponding to mixer 314 of FIG. 3). The output signals from mixers 314₁ and 314₂ may be combined (e.g., via combiner 410) and provided to an input of the PA 318, as shown. The PA 318 generates a signal for transmission via antenna 306 through a matching network 406.

For reception, the first transceiver 402 may include a low-noise amplifier (LNA) 324 receiving a signal from the antenna 306 (e.g., through the matching network 406). The output of the LNA 324 may be coupled to inputs of mixers 326₁ and 326₂ (e.g., corresponding to mixer 326 of FIG. 3). The outputs of mixers 326₁ and 326₂ may be coupled to inputs of filters 328₁ and 328₂ (e.g., corresponding to BBF 328 of FIG. 3) and ADCs 330₁ and 330₂ (e.g., corresponding to ADC 330 of FIG. 3).

The second transceiver 404 may have a similar architecture to that of the first transceiver 402. As shown, the transceiver 402, 404 may share a common voltage rail 408 (e.g., a common power supply path). For example, the same power supply voltage VDD (e.g., a 1.8 V supply voltage) may be provided to the power supply inputs of the PAs of the transceivers 402, 404. The common supply path may provide a path for the electrical coupling of harmonics between the transmitters. For instance, as described herein, the second harmonic of a signal from the first transmitter may electrically couple to the second transmitter, causing an FCC violation. In some aspects, to address the second harmonic signal electrically coupling between the transmitters, head switches may be added to the supply paths for the respective transmitters as described in more detail herein. In some aspects, the 2G transceiver and the 5G transceiver may share one or more antennas, such as the antenna 306.

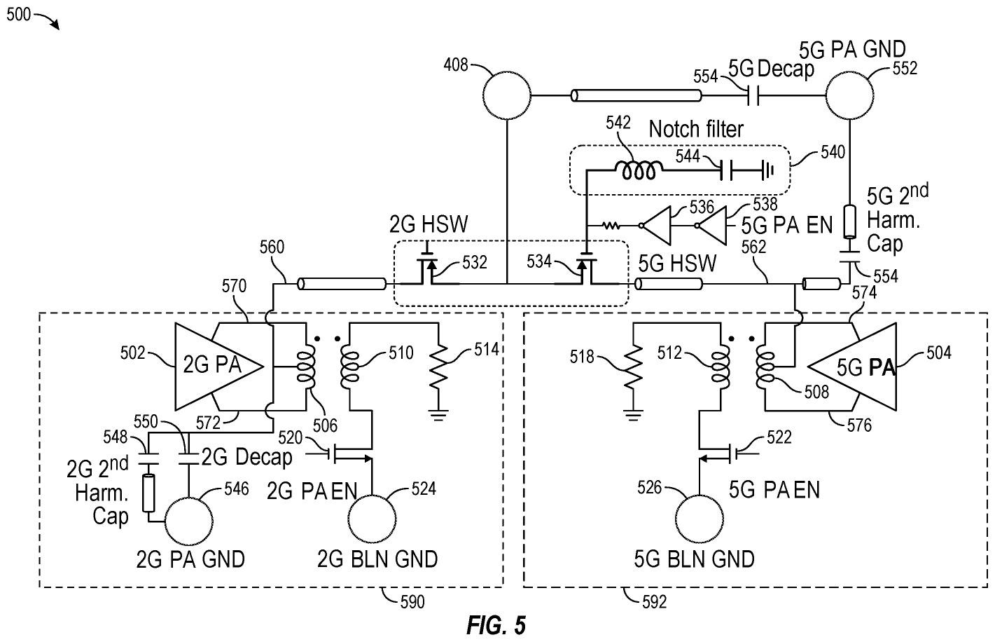

FIG. 5 illustrates transmitter circuitry 500 including multiple transmitters having a shared supply path and respective head switches, in accordance with certain aspects of the present disclosure. As shown, the transmitter circuitry 500 may include a transmitter 590 with a 2G transmitter PA 502 and a transmitter 592 with a 5G transmitter PA 504. The outputs of the PAs 502, 504 drive respective primary windings 506, 508 of respective transformers (e.g., balanced-unbalanced (balun) transformers). For example, differential outputs 570, 572 of the PA 502 may be coupled to first and second terminals of the primary winding 506. Similarly, differential outputs 574, 576 of the PA 504 may be coupled to first and second terminals of the primary winding 508. The primary winding 506 is magnetically coupled to a secondary winding 510. A resistive element 514 may be coupled between a first terminal of the secondary winding 510 and a reference potential node (e.g., ground node). The primary winding 508 may be magnetically coupled to a secondary winding 512. A resistive element 518 may be coupled between a first terminal of the secondary winding 512 and a reference potential node (e.g., ground node).

As shown, a transistor 520 may be coupled between a second terminal of the secondary winding 510 and a reference potential node 524 (e.g., a 2G balun ground, labeled “2G BLN GND”). The transistor 520 may be controlled to enable the PA 502. The transistor 520 may be driven by a 2G PA enable signal (labeled “2G PA EN”). Similarly, a transistor 522 may be coupled between a second terminal of the secondary winding 512 and a reference potential node 526 (e.g., a 5G balun ground, labeled “5G BLN GND”). The transistor 522 may be controlled to enable the PA 504. The transistor 522 may be driven by a 5G PA enable signal (labeled “5G PA EN”), as shown. In some aspects, the second terminals of the secondary windings 510, 512 may be coupled to respective low-noise amplifiers (LNAs) for respective receivers (not shown).

As shown, a head switch (HSW) transistor 532 may be coupled between a supply node 560 for the first transmitter 590 and the common voltage rail 408, and a HSW transistor 534 may be coupled between a supply node 562 for the second transmitter 592 and the common voltage rail 408. The transistor 532 has a drain coupled to the supply node 560 and a source coupled to the voltage rail 408, and the transistor 534 has a drain coupled to the supply node 562 and a source coupled to the voltage rail 408. The supply nodes 560, 562 may be coupled to respective taps (e.g., center taps) of the primary windings 506, 508. In other words, the tap (e.g., center tap) of the primary winding 506 and the tap (e.g., center tap) of the primary winding 508 may be coupled to the common voltage rail 408 through respective HSW transistors 532, 534 (e.g., labeled “2G HSW” and “5G HSW”) as shown. The HSW transistors 532, 534 provide isolation between the supply node 560 (e.g., tap of the primary winding 506) and the supply node 562 (e.g., the tap of the primary winding 508) so that the electrical coupling of the second harmonic signal between the first and second transmitters is reduced.

As shown, a gate of the transistor 534 may be driven by the 5G PA enable signal (e.g., through inverters 536, 538). When the first transmitter 590 is turned on, the transistor 532 may be turned on to power the first transmitter (e.g., provide power to the supply node 560 of transmitter 590), while the transistor 534 is turned off via the PA enable signal for the second transmitter. Similarly, when the second transmitter 592 is turned on, the transistor 534 may be turned on to power the second transmitter (e.g., provide power to the supply node 562 of transmitter 592), while the transistor 532 is turned off.

In some aspects, a filter 540 may be coupled to the gate of the transistor 534 to further suppress the second harmonic from the first transmitter. The filter 540 may be implemented as a notch filter, in some aspects. The filter 540 may include an inductive element 542 coupled in series with a capacitive element 544, as shown, which may function as a passive notch filter. The inductive element 542 and the capacitive element 544 may be configured so that the filter 540 attenuates signals at the second harmonic frequency of the first transmitter.

The head switch transistors 532, 534 attenuate a signal (e.g., the second harmonic signal) from the PA of the first transmitter to the second transmitter output by increasing isolation of the shared supply path. The filter 540 may be used to further suppress (e.g., attenuate) the second harmonic signal or other harmonic signals. In other words, high frequency signals (e.g., the second harmonic signal) may be electrically coupled from the source of transistor 534 to the gate of the transistor 534 through a source-to-gate parasitic capacitance of transistor 534. Without filter 540, at least a portion of these high frequency signals (e.g., the second harmonic signal) may still reach the second transmitter through a gate-to-drain parasitic capacitance of the transistor 534. Thus, the notch filter may attenuate a signal (e.g., the second harmonic signal) reaching the gate of the transistor 534, as shown. Using the transistors 532, 534 and the notch filter may have little to no impact on the first and second transmitter performance (e.g., efficiency, output power, and linearity).

As shown, the tap of the primary winding 506 may be coupled to a reference potential node 546 (e.g., labeled “2G PA GND”) through a capacitive element 548 (which may implement a 2G second harmonic filter and is labeled “2G 2^{nd} Harm. Cap”), and in some aspects, a decoupling capacitive element 550 (labeled “2G Decap”), as shown. Similarly, the tap of the primary winding 508 may be coupled to a reference potential node 552 (e.g., labeled “5G PA GND”) through a capacitive element 554 (e.g., which may implement a 5G second harmonic filter and is labeled “5G 2^{nd} Harm. Cap”). As shown, a decoupling capacitive element 554 (labeled “5G Decap”) may be coupled between the voltage rail 408 and the reference potential node 552.

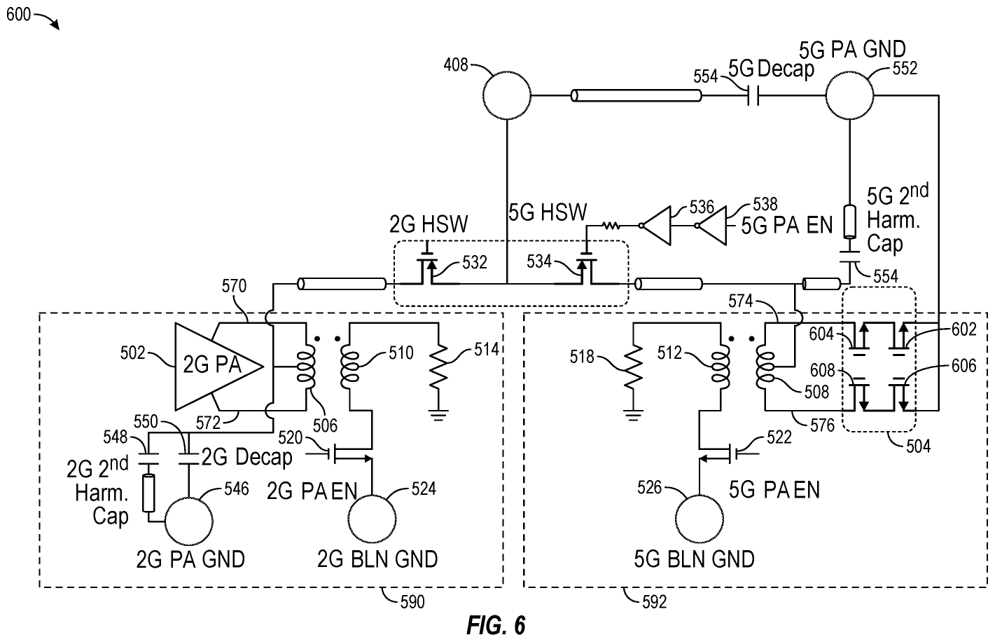

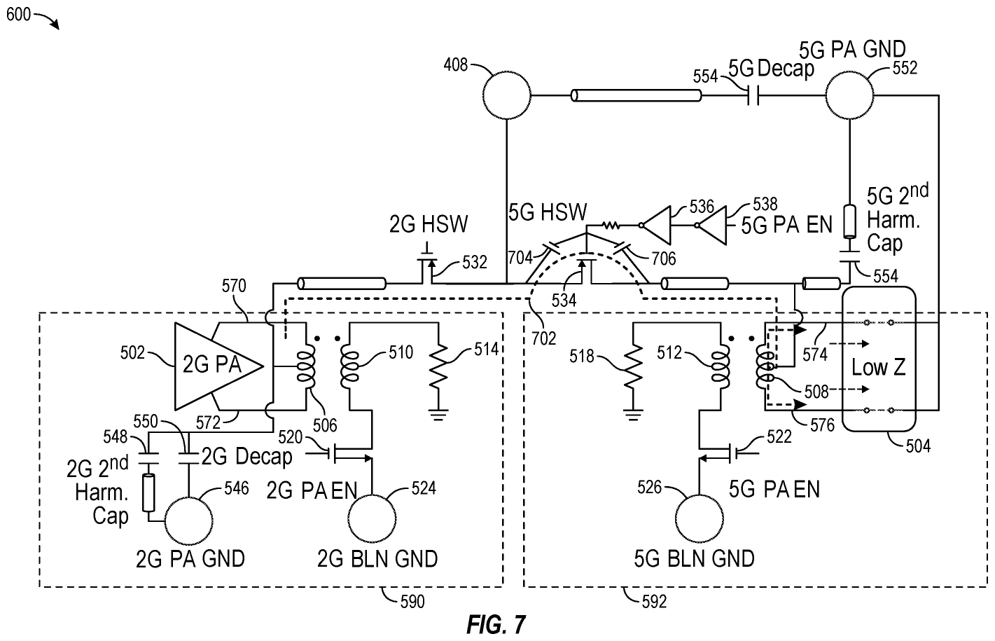

FIGS. 6 and 7 illustrate transmitter circuitry 600 including multiple transmitters having a shared supply path and respective head switches with a low-impedance path through a PA, in accordance with certain aspects of the present disclosure. In some aspects, when operating the first transmitter 590, the PA 504 may be used as a switch to suppress the second harmonic frequency signal from the 2G transmitter. For example, as shown, the PA 504 may include series transistors 602, 604 between the PA output 574 and the reference potential node 552 and series transistors 606, 608 between the PA output 576 and the reference potential node 552. During the first transmitter operation, the transistors 602, 604, 606, 608 may be turned on (e.g., using high bias voltage at gates of the transistors 602, 604, 606, 608).

The head switch (e.g., transistor 534) on the second transmitter supply path may be turned off to prevent (or at least reduce) current consumption by the second transmitter during the first transmitter operation. Meanwhile, the PA 504 series transistors may be turned on to provide a low impedance path (labeled “low Z” in FIG. 7) for the primary winding of the second transmitter. In other words, the transistors 602, 604, 606, 608 may be turned on to provide a low-impedance path through the PA 504. For instance, as shown in FIG. 7, the second harmonic signal 702 (or other high frequency signal) may be provided from the outputs of the PA 502 (e.g., from the tap of the primary winding 506), across the source-to-gate parasitic capacitance 704 of the transistor 534, across the gate-to-drain parasitic capacitance 706 of the transistor 534, to the tap of the primary winding 508, and across the series switches of the PA 504 to the reference potential node 552. In other words, because the 5G PA maintains low impedance during the 2G transmit operation, the second harmonic signal (or other high frequency signal) electrically coupled to the 5G PA primary winding 508 through the parasitic capacitances of the 5G head switch (e.g., transistor 534) is discharged to the 5G PA ground (reference potential node 552). In some aspects, a transformer switch (TRSW) (e.g., transistor 522) in the 5G secondary winding 512 may be turned on to achieve further suppression of the second harmonic signal (or other high frequency signal). As a result, the second harmonic signal (or other high frequency signal) may be reduced to meet FCC (or other agency) standards. Certain aspects described herein may result in little to no increased: (i) power consumption from the first and second transmitters and (ii) chip area consumption.

While the example transmitters described herein are implemented for 2G and 5G technologies, aspects of the present disclosure may be implemented for sharing a voltage rail between any suitable transmitters. Moreover, while examples provided herein are described with respect to a second harmonic signal to facilitate understanding, the aspects of the present disclosure may be applied to reduce electrical coupling for any signal component (e.g., any signal component from the first transmitter 590).

### Example Operations for Wireless Communication

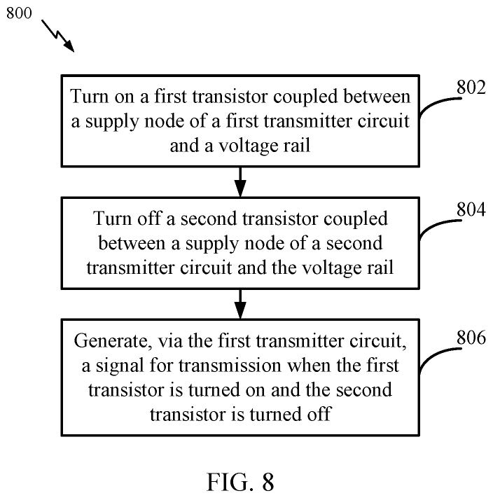

FIG. 8 is a flow diagram illustrating example operations 800 for wireless communication, in accordance with certain aspects of the present disclosure. The operations 800 may be performed, for example, by transmitter circuitry, such as the transmitter circuitry 500 or 600.

At block 802, the transmitter circuitry may turn on a first transistor (e.g., HSW transistor 532 of FIGS. 5-7) coupled between a supply node (e.g., supply node 560) of a first transmitter circuit (e.g., transmitter 590) and a voltage rail (e.g., voltage rail 408). At block 804, the transmitter circuitry turns off a second transistor (e.g., HSW transistor 534) coupled between a supply node (e.g., supply node 562) of a second transmitter circuit (e.g., transmitter 592) and the voltage rail. At block 806, the transmitter circuit generates, via the first transmitter circuit, a signal for transmission when the first transistor is turned on and the second transistor is turned off.

In some aspects, the signal for transmission may be generated via a first amplifier (e.g., PA 502) of the first transmitter circuit having outputs coupled to a primary winding (e.g., primary winding 506) of a first transformer. The supply node of the first transmitter circuit may be coupled to a tap of the primary winding of the first transmitter circuit. In some aspects, the first transformer may include a secondary winding (e.g., secondary winding 510) coupled to an antenna for the transmission of the signal.

In some aspects, the transmitter circuitry may attenuate, via a filter (e.g., filter 540), a signal at a gate of the second transistor. The filter may include a capacitive element (e.g., capacitive element 544) in series with an inductive element (e.g., inductive element 542). The signal at the gate of the second transistor may include a second harmonic signal from the first transmitter circuit.

In some aspects, the transmitter circuitry may close one or more switches (e.g., turn on transistors 602, 604, 606, 608 shown in FIG. 6) of an amplifier (e.g., PA 504) of the second transmitter circuit. The one or more switches may be coupled between the supply node of the second transmitter circuit and a reference potential node (e.g., reference potential node 552). The signal may be generated for transmission at block 806 when the one or more switches are turned on.

### Example Aspects

In addition to the various aspects described above, specific combinations of aspects are within the scope of the present disclosure, some of which are detailed below:

Aspect 1: An apparatus for wireless communication, comprising: a first transmitter circuit including a first amplifier; a second transmitter circuit including a second amplifier; a first transistor coupled between a supply node of the first transmitter circuit and a voltage rail; a second transistor coupled between a supply node of the second transmitter circuit and the voltage rail; and a filter coupled to a gate of the second transistor.

Aspect 2: The apparatus of Aspect 1, wherein: outputs of the first amplifier are coupled to a primary winding of a first transformer, the supply node of the first transmitter circuit being coupled to a tap of the primary winding of the first transformer; and outputs of the second amplifier are coupled to a primary winding of a second transformer, the supply node of the second transmitter circuit being coupled to a tap of the primary winding of the second transformer.

Aspect 3: The apparatus of Aspect 2, wherein each of the first transformer and the second transformer comprises a secondary winding coupled to an antenna.

Aspect 4: The apparatus according to any of Aspects 1-3, wherein the filter comprises a notch filter.

Aspect 5: The apparatus according to any of Aspects 1-4, wherein the filter is configured to attenuate a harmonic signal from the first transmitter circuit.

Aspect 6: The apparatus according to any of Aspects 1-5, wherein the second transmitter circuit comprises an amplifier having one or more switches coupled between the supply node of the second transmitter circuit and a reference potential node.

Aspect 7: The apparatus of Aspect 6, wherein the one or more switches are configured to be closed during operation of the first transmitter circuit.

Aspect 8: The apparatus according to any of Aspects 1-7, wherein: the first transistor comprises a drain coupled to the supply node of the first transmitter circuit and a source coupled to the voltage rail; and the second transistor comprises a drain coupled to the supply node of the second transmitter circuit and a source coupled to the voltage rail.

Aspect 9: The apparatus according to any of Aspects 1-8, wherein the first transmitter comprises a 2.4 GHz WiFi transmitter and the second transmitter comprises a 5 GHz WiFi transmitter.

Aspect 10: The apparatus of Aspect 9, wherein the 2 GHz WiFi transmitter and the 5 GHz WiFi transmitter are configured to share a common antenna.

Aspect 11: A method for wireless communication, comprising: turning on a first transistor coupled between a supply node of a first transmitter circuit and a voltage rail; turning off a second transistor coupled between a supply node of a second transmitter circuit and the voltage rail; and generating, via the first transmitter circuit, a signal for transmission when the first transistor is turned on and the second transistor is turned off.

Aspect 12: The method of Aspect 11, wherein the signal for transmission is generated via a first amplifier of the first transmitter circuit having outputs coupled to a primary winding of a transformer, the supply node of the first transmitter circuit being coupled to a tap of the primary winding of the transformer.

Aspect 13: The method of Aspect 12, wherein the transformer comprises a secondary winding coupled to an antenna for the transmission of the signal.

Aspect 14: The method according to any of Aspects 11-13, further comprising attenuating, via a filter, a signal at a gate of the second transistor.

Aspect 15: The method of Aspect 14, wherein the filter comprises a notch filter.

Aspect 16: The method of Aspect 14 or 15, wherein the signal at the gate of the second transistor comprises a harmonic signal from the first transmitter circuit.

Aspect 17: The method according to any of Aspects 11-16, further comprising closing one or more switches of an amplifier of the second transmitter circuit, wherein the one or more switches are coupled between the supply node of the second transmitter circuit and a reference potential node, and wherein the signal is generated for transmission when the one or more switches are closed.

Aspect 18: The method according to any of Aspects 11-17, wherein: the first transistor comprises a drain coupled to the supply node of the first transmitter circuit and a source coupled to the voltage rail; and the second transistor comprises a drain coupled to the supply node of the second transmitter circuit and a source coupled to the voltage rail.

Aspect 19: A wireless device, comprising: a first antenna; a second antenna; a 2 GHz WiFi transmitter circuit coupled to the first antenna; a 5 GHz WiFi transmitter circuit coupled to the second antenna; a first transistor coupled between a supply node of the first transmitter circuit and a voltage rail; and a second transistor coupled between a supply node of the second transmitter circuit and the voltage rail.

Aspect 20: The wireless device of Aspect 19, wherein the first antenna and the second antenna are the same antenna.

The above description provides examples, and is not limiting of the scope, applicability, or examples set forth in the claims. Changes may be made in the function and arrangement of elements discussed without departing from the scope of the disclosure. Various examples may omit, substitute, or add various procedures or components as appropriate. For instance, the methods described may be performed in an order different from that described, and various steps may be added, omitted, or combined. Also, features described with respect to some examples may be combined in some other examples. For example, an apparatus may be implemented or a method may be practiced using any number of the aspects set forth herein. In addition, the scope of the disclosure is intended to cover such an apparatus or method which is practiced using other structure, functionality, or structure and functionality in addition to, or other than, the various aspects of the disclosure set forth herein. It should be understood that any aspect of the disclosure disclosed herein may be embodied by one or more elements of a claim.

The various operations of methods described above may be performed by any suitable means capable of performing the corresponding functions. The means may include various hardware and/or software component(s) and/or module(s), including, but not limited to a circuit, an application-specific integrated circuit (ASIC), or processor. Generally, where there are operations illustrated in figures, those operations may have corresponding counterpart means-plus-function components.

As used herein, a phrase referring to “at least one of” a list of items refers to any combination of those items, including single members. As an example, “at least one of: a, b, or c” is intended to cover: a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c or any other ordering of a, b, and c).

The methods disclosed herein comprise one or more steps or actions for achieving the described method. The method steps and/or actions may be interchanged with one another without departing from the scope of the claims. In other words, unless a specific order of steps or actions is specified, the order and/or use of specific steps and/or actions may be modified without departing from the scope of the claims.

It is to be understood that the claims are not limited to the precise configuration and components illustrated above. Various modifications, changes, and variations may be made in the arrangement, operation, and details of the methods and apparatus described above without departing from the scope of the claims.

1. An apparatus for wireless communication, comprising:
a first transmitter circuit including a first amplifier;
a second transmitter circuit including a second amplifier;
a first transistor coupled between a supply node of the first transmitter circuit and a voltage rail;
a second transistor coupled between a supply node of the second transmitter circuit and the voltage rail; and
a filter coupled to a gate of the second transistor.

2. The apparatus of claim 1, wherein:
outputs of the first amplifier are coupled to a primary winding of a first transformer, the supply node of the first transmitter circuit being coupled to a tap of the primary winding of the first transformer; and
outputs of the second amplifier are coupled to a primary winding of a second transformer, the supply node of the second transmitter circuit being coupled to a tap of the primary winding of the second transformer.

3. The apparatus of claim 2, wherein each of the first transformer and the second transformer comprises a secondary winding coupled to an antenna.

4. The apparatus of claim 1, wherein the filter comprises a notch filter.

5. The apparatus of claim 1, wherein the filter is configured to attenuate a harmonic signal from the first transmitter circuit.

6. The apparatus of claim 1, wherein the second transmitter circuit comprises an amplifier having one or more switches coupled between the supply node of the second transmitter circuit and a reference potential node.

7. The apparatus of claim 6, wherein the one or more switches are configured to be closed during operation of the first transmitter circuit.

8. The apparatus of claim 1, wherein:
the first transistor comprises a drain coupled to the supply node of the first transmitter circuit and a source coupled to the voltage rail; and
the second transistor comprises a drain coupled to the supply node of the second transmitter circuit and a source coupled to the voltage rail.

9. The apparatus of claim 1, wherein the first transmitter circuit comprises a 2.4 GHz WiFi transmitter and the second transmitter circuit comprises a 5 GHz WiFi transmitter.

10. The apparatus of claim 9, wherein the 2.4 GHz WiFi transmitter and the 5 GHz WiFi transmitter are configured to share a common antenna.

11. A method for wireless communication, comprising:
turning on a first transistor coupled between a supply node of a first transmitter circuit and a voltage rail;
turning off a second transistor coupled between a supply node of a second transmitter circuit and the voltage rail; and
generating, via the first transmitter circuit, a signal for transmission when the first transistor is turned on and the second transistor is turned off.

12. The method of claim 11, wherein the signal for transmission is generated via a first amplifier of the first transmitter circuit having outputs coupled to a primary winding of a transformer, the supply node of the first transmitter circuit being coupled to a tap of the primary winding of the transformer.

13. The method of claim 12, wherein the transformer comprises a secondary winding coupled to an antenna for the transmission of the signal.

14. The method of claim 11, further comprising attenuating, via a filter, a signal at a gate of the second transistor.

15. The method of claim 14, wherein the filter comprises a notch filter.

16. The method of claim 14, wherein the signal at the gate of the second transistor comprises a harmonic signal from the first transmitter circuit.

17. The method of claim 11, further comprising closing one or more switches of an amplifier of the second transmitter circuit, wherein the one or more switches are coupled between the supply node of the second transmitter circuit and a reference potential node, and wherein the signal is generated for transmission when the one or more switches are closed.

18. The method of claim 11, wherein:
the first transistor comprises a drain coupled to the supply node of the first transmitter circuit and a source coupled to the voltage rail; and
the second transistor comprises a drain coupled to the supply node of the second transmitter circuit and a source coupled to the voltage rail.

19. A wireless device, comprising:
a first antenna;
a second antenna;
a 2 GHz WiFi transmitter circuit coupled to the first antenna;
a 5 GHz WiFi transmitter circuit coupled to the second antenna;
a first transistor coupled between a supply node of the 2 GHz WiFi transmitter circuit and a voltage rail; and
a second transistor coupled between a supply node of the 5 GHz WiFi transmitter circuit and the voltage rail.

20. The wireless device of claim 19, wherein the first antenna and the second antenna are the same antenna.
